(19) United States
(12) Patent Application Publication
(10) Pub. No.: US 2025/0338701 A1
(43) Pub. Date: Oct. 30, 2025

(54) MICRO LED ARRAY AND MICRO LED DISPLAY PANEL

(71) Applicant: JADE BIRD DISPLAY (SHANGHAI) LIMITED, SHANGHAI (CN)

(72) Inventors: Weisin TAN, Shanghai (CN); Qunchao XU, Shanghai (CN); Zhichen GU, Shanghai (CN)

(21) Appl. No.: 19/190,551

(22) Filed: Apr. 25, 2025

(30) Foreign Application Priority Data
Apr. 26, 2024 (WO) PCT/CN2024/090045

(51) Int. Cl. H10H 29/85; H01L 25/075; H10H 29/856

(52) U.S. Cl. CPC H10H 29/8585; H01L 25/0753; H10H 29/856; H10H 29/857; H10H 29/8581

(57) ABSTRACT

A micro LED array includes a plurality of micro LED structures, wherein each of the micro LED structure includes: a mesa structure; a first thermal conductive layer formed surrounding a sidewall of the mesa structure, wherein a material of the first thermal conductive layer is an electrically insulative material with high thermal conductivity; and a bottom connect structure provided at a bottom of the mesa structure to electrically connect the mesa structure to a bottom pad of an integrated circuit (IC) backplane.

### CROSS-REFERENCE TO RELATED APPLICATIONS

The present disclosure claims the benefits of priority to PCT Application No. PCT/CN 2024/090045, filed on Apr. 26, 2024, which is incorporated herein by reference in its entirety.

### TECHNICAL FIELD

The present disclosure generally relates to micro LED manufacturing technology, and more particularly, to a micro LED array and a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

Generally, a micro LED display panel includes an array of micro LEDs. Each micro LED may generate heat when emitting light. However, high temperature may impact the performance of the micro LED display panel. Therefore, there is a challenge to improve a heat dissipation effect.

### SUMMARY OF THE DISCLOSURE

Embodiments of the present disclosure provide a micro LED array. The micro LED array includes a plurality of micro LED structures, each of the micro LED structure including: a mesa structure; a first thermal conductive layer formed surrounding a sidewall of the mesa structure, wherein a material of the first thermal conductive layer is an electrically insulative material with high thermal conductivity; and a bottom connect structure provided at a bottom of the mesa structure to electrically connect the mesa structure to a bottom pad of an integrated circuit (IC) backplane.

Embodiments of the present disclosure also provide a micro LED display panel. The micro LED display panel includes: an integrated circuit (IC) backplane comprising a bottom pad array, the bottom pad array comprising a plurality of bottom pads; and above described micro LED array provided on the IC backplane; wherein one micro LED structure of the plurality of micro LED structures is electrically connected with one bottom pad of the plurality of bottom pads.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural cross-sectional diagram of an exemplary micro LED display panel, according to some embodiments of the present disclosure.

FIG. 2 illustrates a structural cross-sectional diagram of another exemplary micro LED display panel, according to some embodiments of the present disclosure.

FIG. 3 illustrates a structural cross-sectional diagram of another exemplary micro LED display panel, according to some embodiments of the present disclosure.

FIG. 4 illustrates a structural cross-sectional diagram of another exemplary micro LED display panel, according to some embodiments of the present disclosure.

FIG. 5 illustrates a structural cross-sectional diagram of another exemplary micro LED display panel, according to some embodiments of the present disclosure.

FIG. 6 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED display panel having improved heat dissipation efficiency.

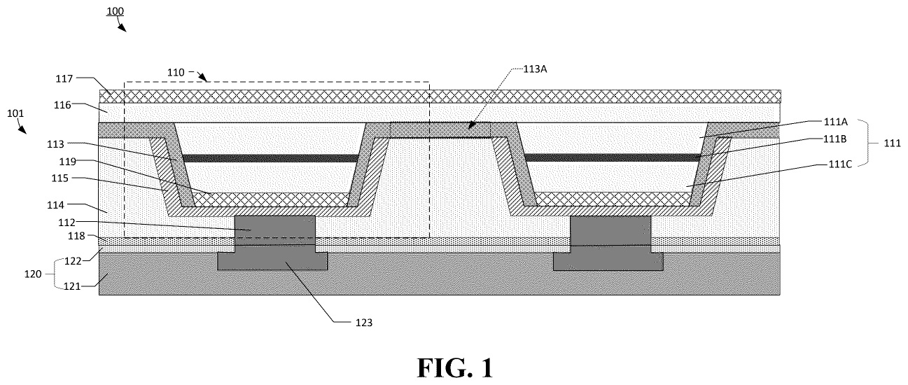

FIG. 1 illustrates a structural cross-sectional diagram of an exemplary micro LED display panel 100, according to some embodiments of the present disclosure. Micro LED display panel 100 includes a micro LED array 101 and an IC (integrated circuit) backplane 120. Micro LED array 101 is located on IC backplane 120 to form an image display area of micro LED display panel 100. Micro LED array 101 includes a plurality of micro LED structures 110. FIG. 1 shows two complete micro LED structures 110, and only one micro LED structure 110 is described for illustrative purposes. Accordingly, it can be understood that micro LED array 101 may include a plurality of micro LED structures 110. Referring to FIG. 1 micro LED structure 110 includes a mesa structure 111 and a bottom connect structure 112. Bottom connect structure 112 is provided at a bottom of mesa structure 111 to electrically connect mesa structure 111 with a bottom pad 123 of an integrated circuit (IC) backplane 120. In some embodiments, bottom connect structure 112 is a Cu-pad. IC backplane 120 is provided at a bottom of micro LED array 101 for providing control of micro LED array 101.

Micro LED structure 110 further includes a first thermal conductive layer 113 formed surrounding a sidewall of mesa structure 111. A material of first thermal conductive layer 113 is an electrically insulative material with high thermal conductivity, so that first thermal conductive layer 113 can radiate heat generated by mesa structure 111. In some embodiments, a thermal conductivity of the electrically insulative material of first thermal conductive layer 113 is greater than 300 W/mK. For example, the material of first thermal conductive layer 113 may be AlN, SiC, Boron, Nitride, diamond, diamond-like carbon, and the like.

In some embodiments, micro LED array 101 further includes a second thermal conductive layer 114 filled between adjacent ones of micro LED structures 110. A material of second thermal conductive layer 114 is a material with high thermal conductivity and electrically insulative, so that second thermal conductive layer 114 can further radiate heat to the air. For example, a thermal conductivity of the material of second thermal conductive layer 114 is greater than 300 W/mK. In some embodiments, the material of second thermal conductive layer 114 is AlN, SiC, Boron, Nitride, diamond, diamond-like carbon, and the like. In some embodiments, first thermal conductive layer 113 is further formed on a top surface of second thermal conductive layer 114, for example, portion 113A shown in FIG. 1 In some embodiments, a material of first thermal conductive layer 113 and a material of second thermal conductive layer 114 can be the same or different.

In some embodiments, mesa structure 111 includes a P-N structure. For example, mesa structure 111 includes a first semiconductor layer 111A, a second semiconductor layer 111C, and a light emitting layer 111B provided between first semiconductor layer 111A and second semiconductor layer 111C. Light emitting layer 111B can emit red light, green light, or blue light. In some embodiments, an area of a top surface of mesa structure 111 is greater than an area of a bottom surface of mesa structure 111. In some embodiments, an area of a top surface of mesa structure 111 is smaller than an area of bottom surface of mesa structure 111. In some embodiments, first semiconductor layer 111A is an N-type semiconductor layer, and second semiconductor layer 111C is a P-type semiconductor layer. Micro LED array 101 further includes a second N-type semiconductor layer 116 formed on a top of micro LED array 101, so that a continuous N-type semiconductor layer is provided and can electrically connect respective N-type semiconductor layer 111A of mesa structures 111.

In some embodiments, micro LED array 101 further includes a top conductive layer 117 provided on second N-type semiconductor layer 116. In some embodiments, top conductive layer 117 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, as shown in FIG. 1 micro LED structure 110 further includes a reflective layer 115 provided on the sidewall of mesa structure 111 and a bottom surface of mesa structure 111. First thermal conductive layer 113 is provided between the sidewall of mesa structure 111 and reflective layer 115. Reflective layer 115 can reflect light emitted by mesa structure 111 upwards, thereby improving the light emission efficiency and reducing light crosstalk between adjacent ones of micro LED structures. In some embodiments, reflective layer 115 is a mirror layer.

Referring to FIG. 1 in some embodiments, micro LED structure 110 further includes a bottom conductive layer 119 provided between mesa structure 111 and bottom connect structure 112 to provide an ohmic conduct between mesa structure 111 and bottom connect structure 112. First thermal conductive layer 113 is further formed surrounding a sidewall of bottom conductive layer 119. In some embodiments, bottom conductive layer 119 includes an omni-directional reflector (ODR) structure with high reflectivity. In some embodiments, bottom conductive layer 119 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, bottom conductive layer 119 is provided between mesa structure 111 and reflective layer 115 to provide an ohmic conduct between mesa structure 111 and reflective layer 115. Therefore, a bottom of mesa structure 111 is electrically connected with bottom connect structure 112 through bottom conductive layer 119 and reflective layer 115.

In some embodiments, IC backplane 120 further includes an array of bottom pads 123. Each bottom pad 123 corresponds to one micro LED structure 110. In some embodiments, bottom pad 123 is a Cu-pad.

Referring to FIG. 1 micro LED array 101 further includes a first bonding layer 118 provided at a bottom of micro LED array 101. IC backplane 120 includes a second bonding layer 122 and a substrate layer 121. Second bonding layer 122 is provided on a top of substrate layer 121. First bonding layer 118 and second bonding layer 122 are bonded. The bonding layer 118 and 122 may be SiO₂, SiN, SiONx, AlN, Boron Nitride, SiC, diamond, diamond-like carbon or a combination thereof. The bonding procedure may be accomplished using a covalent bonding process.

In some embodiments, a material of first bonding layer 118 and second bonding layer 122 is an electrically insulative material with high thermal conductivity. In some embodiments, a thermal conductivity of the electrically insulative material of first bonding layer 118 and second bonding layer 122 is greater than 300 W/mK. For example, the material of first bonding layer 118 and second bonding layer 122 may be AlN, SiC, Boron, Nitride, diamond, diamond-like carbon, and the like. It can be understood that a material of the first bonding layer and a material of the second bonding layer can be the same or different. In some embodiments, the material of first bonding layer 118 is the same as the material of second thermal conductive layer 114.

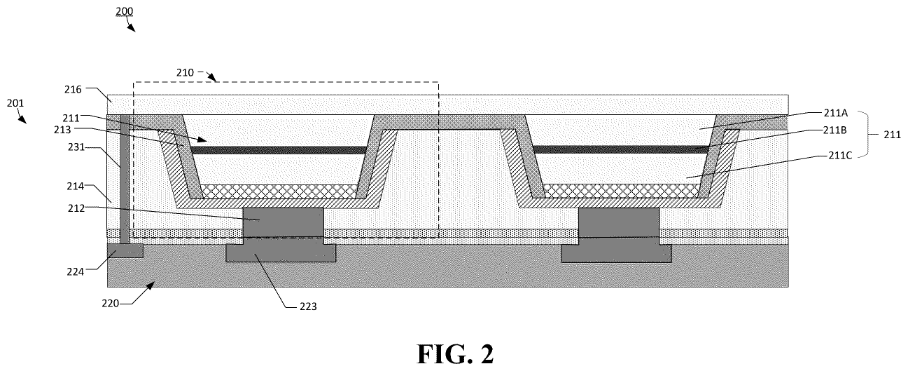

FIG. 2 illustrates a structural cross-sectional diagram of another exemplary micro LED display panel 200, according to some embodiments of the present disclosure. Micro LED display panel 200 includes a micro LED array 201 and an IC (integrated circuit) backplane 220. Micro LED array 201 is located on IC backplane 220 to form an image display area of micro LED display panel 200. Micro LED array 201 includes a plurality of micro LED structures 210. FIG. 2 shows two complete micro LED structures 210, and only one micro LED structure 210 is described for illustrative purposes. Accordingly, it can be understood that micro LED array 201 may include a plurality of micro LED structures 210. Referring to FIG. 2 similar to micro LED display panel 100 shown in FIG. 1 micro LED structure 210 includes a mesa structure 211 and a bottom connect structure 212. Bottom connect structure 212 is provided at a bottom of mesa structure 211 to connect mesa structure 211 with a bottom pad 223 of an integrated circuit (IC) backplane 220. In some embodiments, bottom connect structure 212 is a Cu-pad. IC backplane 220 is provided at a bottom of micro LED array 201 for providing control of micro LED array 201.

Micro LED array 201 further includes a first thermal conductive layer 213 formed surrounding a sidewall of mesa structure 211 and a second thermal conductive layer 214 filled between adjacent ones of micro LED structures 210. As shown in FIG. 2 micro LED array 201 further includes a second N-type semiconductor layer 216 formed on a top of micro LED array 201, so that a continuous N-type semiconductor layer is provided and can electrically connect respective N-type semiconductor layers 211A of mesa structure 211. In this example, micro LED array 201 further includes a top connecting structure 231 provided passing through second thermal conductive layer 214 to connect second N-type semiconductor layer 216 with a top pad 224 on IC backplane 220.

Description of other features of micro LED display panel 200 may be found by referring to such features described above with reference to FIG. 1 which will not be repeated here.

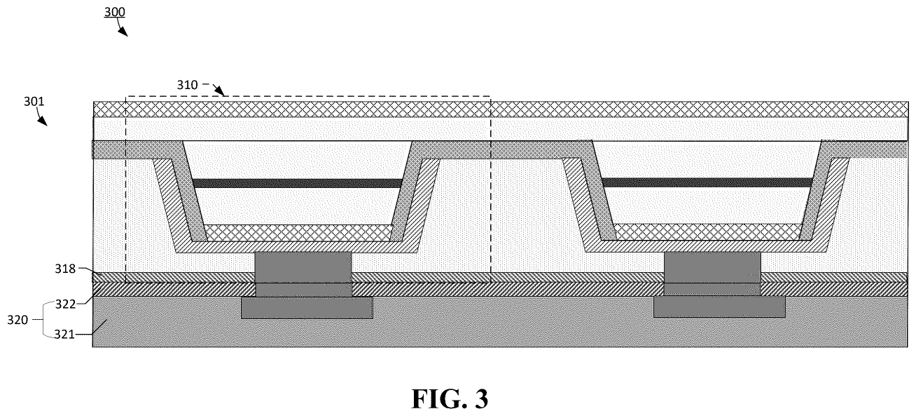

FIG. 3 illustrates a structural cross-sectional diagram of another exemplary micro LED display panel 300, according to some embodiments of the present disclosure. Micro LED display panel 300 includes a micro LED array 301 and an IC (integrated circuit) backplane 320. Micro LED array 301 is located on IC backplane 320 to form an image display area of micro LED display panel 300. Micro LED array 301 includes a plurality of micro LED structures 310.

As shown in FIG. 3, micro LED array 301 further includes a first bonding layer 318 provided at a bottom of micro LED array 301. IC backplane 320 includes a second bonding layer 322 and a substrate layer 321, second bonding layer 322 being provided on a top of substrate layer 321. First bonding layer 318 and second bonding layer 322 are bonded.

In this example, a material of first bonding layer 318 and second bonding layer 322 is a dielectric material. For example, the material of first bonding layer 318 and second bonding layer 322 may be SiO₂, SiN, SiCN, or the like. It can be understood that a material of the first bonding layer and a material of the second bonding layer can be the same or different. In some embodiments, the material of second bonding layer 322 is the same as the material of substrate layer 321.

Description of other features of micro LED display panel 300 may be found by referring to such features described above with reference to FIG. 1 which will not be repeated here.

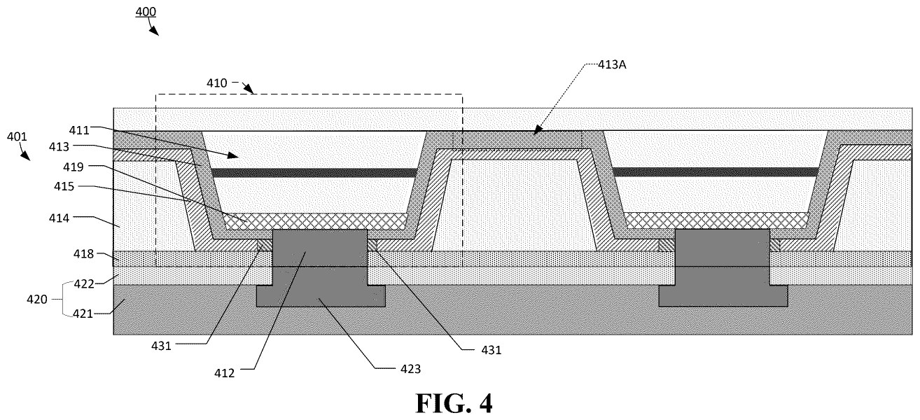

FIG. 4 illustrates a structural cross-sectional diagram of another exemplary micro LED display panel 400, according to some embodiments of the present disclosure. Micro LED display panel 400 includes a micro LED array 401 and an IC (integrated circuit) backplane 420. Micro LED array 401 is located on IC backplane 420 to form an image display area of micro LED display panel 400. Micro LED array 401 includes a plurality of micro LED structures 410. FIG. 4 shows two complete micro LED structures 410, and only one micro LED structure 410 is described for illustrative purposes. Accordingly, it can be understood that micro LED array 401 may include a plurality of micro LED structures 410. Referring to FIG. 4, similar to micro LED display panel 100 shown in FIG. 1 micro LED structure 410 includes a mesa structure 411 and a bottom connect structure 412. Bottom connect structure 412 is provided at a bottom of mesa structure 411 to connect mesa structure 411 with a bottom pad 423 of an integrated circuit (IC) backplane 420. Micro LED array 401 further includes a reflective layer 415 provided on the sidewall of mesa structure 411 and a bottom surface of mesa structure 411. A first thermal conductive layer 413 is provided between the sidewall of mesa structure 411 and reflective layer 415. Bottom connect structure 412 passes through reflective layer 415, and bottom connect structure 412 passes through first thermal conductive layer 413 and reflective layer 415 to connect the bottom of mesa structure 411 with bottom pad 423. Mirco LED structure 401 further includes an isolation ring 431 provided between bottom connect structure 412 and reflective layer 415 to isolate bottom connect structure 412 from the reflective layer 415. It can be understood that in some embodiments, isolation ring 431 is provided around bottom connect structure 412. In some embodiments, a material of isolation ring 431 is a dielectric material, for example, SiO₂.

In some embodiments, micro LED structure 410 further includes a bottom conductive layer 419 provided at a bottom of mesa structure 411. Bottom connect structure 412 passes through first thermal conductive layer 413 and reflective layer 415 to connect to bottom conductive layer 419. Bottom conductive layer 419 can provide an ohmic contact between mesa structure 411 and bottom connect structure 412. In some embodiments, bottom conductive layer 419 includes an omni-directional reflector (ODR) structure with high reflectivity. In some embodiments, bottom conductive layer 419 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

As shown in FIG. 4, micro LED array 401 further includes a second thermal conductive layer 414 filled between adjacent ones of micro LED structures 410. In this example, first thermal conductive layer 413 is further formed on a top surface of the second thermal conductive layer 414, for example, portion 413A, and reflective layer 415 is further provided between first thermal conductive layer 413 and second thermal conductive layer 414.

In some embodiments, the material of second thermal conductive layer 414 is electrically insulative or electrically conductive. For example, in some embodiments, the material of second thermal conductive layer 414 is AlN, SiC, Boron, Nitride, diamond, or diamond-like carbon. In some embodiments, the material of second thermal conductive layer 414 is Ag, Cu, Al, Graphite, or Graphene.

Referring to FIG. 4, micro LED array 401 further includes a first bonding layer 418 provided at a bottom of micro LED array 401. IC backplane 420 includes a second bonding layer 422 and a substrate layer 421, second bonding layer 422 being provided on a top of substrate layer 421. First bonding layer 418 and second bonding layer 422 are bonded. The bonding layer 418 and 422 may be SiO₂, SiN, SiONx, AlN, Boron Nitride, SiC, diamond, diamond-like carbon or a combination thereof. The bonding procedure may be accomplished using a covalent bonding process.

In some embodiments, a material of first bonding layer 418 and second bonding layer 422 is an electrically insulative material with high thermal conductivity. In some embodiments, a thermal conductivity of the electrically insulative material of first bonding layer 418 and second bonding layer 422 is greater than 300 W/mK. For example, the material of first bonding layer 418 and second bonding layer 422 is AlN, SiC, Boron, Nitride, diamond, or diamond-like carbon. It can be understood that a material of the first bonding layer and a material of the second bonding layer can be the same or different. In some embodiments, the material of first bonding layer 418 is the same as the material of thermal conductive layer 414.

Description of other features of micro LED display panel 400 may be found by referring to such features described above with reference to FIG. 1 which will not be repeated here.

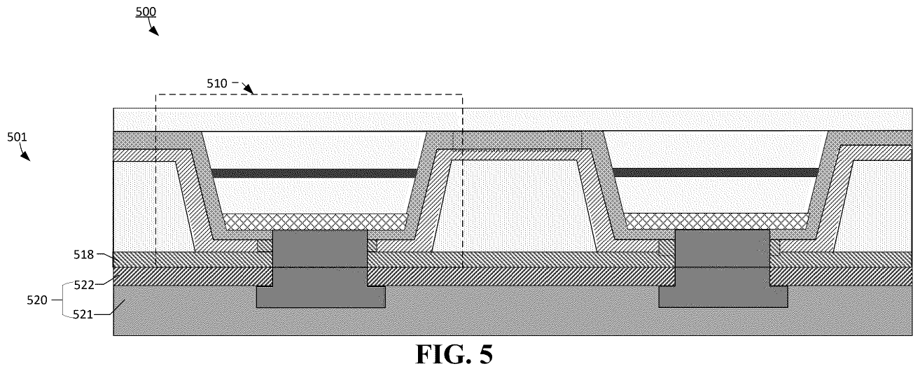

FIG. 5 illustrates a structural cross-sectional diagram of another exemplary micro LED display panel 500, according to some embodiments of the present disclosure. Micro LED display panel 500 includes a micro LED array 501 and an IC (integrated circuit) backplane 520. Micro LED array 501 is located on IC backplane 520 to form an image display area of micro LED display panel 500. Micro LED array 501 includes a plurality of micro LED structures 510.

As shown in FIG. 5, micro LED array 501 further includes a first bonding layer 518 provided at a bottom of micro LED array 501. IC backplane 520 includes a second bonding layer 522 and a substrate layer 521, second bonding layer 522 being provided on a top of substrate layer 521. First bonding layer 518 and second bonding layer 522 are bonded.

In this example, a material of first bonding layer 518 and second bonding layer 522 is a dielectric layer. For example, the material of first bonding layer 518 and second bonding layer 522 is SiO₂, SiN, or SiCN. It can be understood that a material of the first bonding layer and a material of the second bonding layer can be the same or different. In some embodiments, the material of second bonding layer 522 is the same as the material of substrate layer 521.

Description of other features of micro LED display panel 500 may be found by referring to such features described above with reference to FIG. 4, which will not be repeated here.

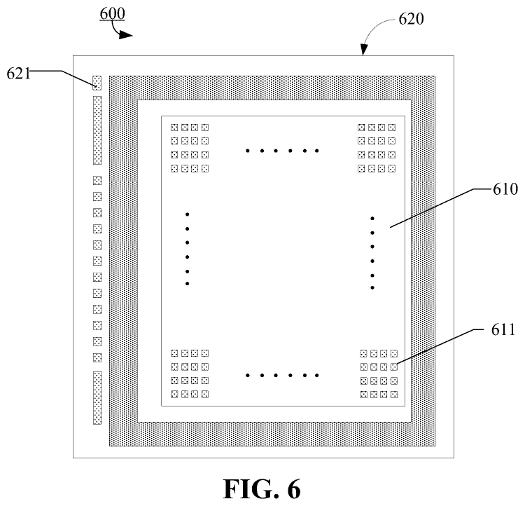

FIG. 6 illustrates a structural diagram showing a top view of a micro LED display panel 600, according to some embodiments of the present disclosure. Referring to FIG. 6, micro LED display panel 600 includes a micro LED array 610 (for example, micro LED array 101, micro LED array 201, micro LED array 301, micro LED array 401, or micro LED array 501) and an IC (integrated circuit) backplane 620. Micro LED array 610 is located on IC backplane 620 to form an image display area of micro LED display panel 600. The rest of the area on IC backplane 620 not covered by micro LED array 610 is formed as a non-functional area. IC backplane 620 is formed at the back surface of micro LED array 610 with a part extending outside of, i.e., not covered by, micro LED array 610. Micro LED array 610 includes a plurality of micro LEDs 611 (for example, micro LED structure 110, micro LED structure 210, or micro LED structure 310, micro LED structure 410, or micro LED structure 510) provided in micro LED array 610. IC backplane 620 is configured to control the plurality of micro LEDs 611. IC backplane 620 may include a bottom pad array (not shown) corresponding to micro LED array 610. The bottom pad array includes a plurality of bottom pads (for example, bottom pad 123, or bottom pad 223), and one bottom pad corresponds to one micro LED 611. One micro LED of the plurality of micro LEDs is electrically connected with one bottom pad of the plurality of the bottom pad.

In some embodiments, a top conductive layer (for example, top conductive layer 117) of the micro LED is interconnected with each of the plurality of micro LEDs. That is, the top conductive layer is continuously formed on a top of micro LED array 610, and connected with every micro LED 611.

In some embodiments, IC backplane 620 further includes a top connected pad 621. The top conductive layer is connected with top connected pad 621, and further may connect to an external circuit.

Each micro LED structure herein (e.g., micro LED structure 110, micro LED structure 210, micro LED structure 310, micro LED structure 410, or micro LED structure 510) has a very small volume. The micro LED structure can be applied in a micro LED display panel. The light emitting area of the micro LED display panel, e.g., micro LED display panel 600, is very small, such as 1 mm×1 mm, 3 mm×5 mm, etc. In some embodiments, the light emitting area is the area of micro LED array 610 in micro LED display panel 600. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 620, is formed at the back surface of micro LED array 610 and is electrically connected with micro LED array 610. IC backplane 620 acquires signals such as image data from outside via signal lines to control corresponding micro LEDs 611 to emit light or not.

It is understood by those skilled in the art that the micro LED display panel is not limited by the structure described above, and may include greater or fewer components than those illustrated, or some components may be combined, or a different component may be utilized.

The embodiments may further be described using the following clauses:
1. A micro LED array comprising a plurality of micro LED structures, each of the micro LED structures comprising:
   a mesa structure;
   a first thermal conductive layer formed surrounding a sidewall of the mesa structure, wherein a material of the first thermal conductive layer is an electrically insulative material with high thermal conductivity; and
   a bottom connect structure provided at a bottom of the mesa structure to electrically connect the mesa structure to a bottom pad of an integrated circuit (IC) backplane.
2. The micro LED array according to clause 1, wherein a thermal conductivity of the electrically insulative material of the first thermal conductive layer is greater than 300 W/mK.
3. The micro LED array according to clause 2, wherein the material of the first thermal conductive layer is AlN, SiC, Boron, Nitride, diamond, or diamond-like carbon.
4. The micro LED array according to clause 1, further comprising a second thermal conductive layer filled between adjacent ones of micro LED structures, wherein a material of the second thermal conductive layer is a material with high thermal conductivity.
5. The micro LED array according to clause 4, wherein a thermal conductivity of the material of the second thermal conductive layer is greater than 300 W/mK.
6. The micro LED array according to clause 5, wherein the material of the second thermal conductive layer is electrically insulative.
7. The micro LED array according to clause 6, wherein the material of the second thermal conductive layer is AlN, SiC, Boron, Nitride, diamond, or diamond-like carbon.
8. The micro LED array according to clause 5, wherein the material of the second thermal conductive layer is electrically conductive.
9. The micro LED array according to clause 8, wherein the material of the second thermal conductive layer is Ag, Cu, Al, Graphite, or Graphene.
10. The micro LED array according to any one of clauses 4 to 9, further comprising a reflective layer provided on the sidewall of the mesa structure and a bottom surface of the mesa structure, wherein the first thermal conductive layer is provided between the sidewall of the mesa structure and the reflective layer.
11. The micro LED array according to clause 10, wherein the first thermal conductive layer is further formed on a top surface of the second thermal conductive layer.
12. The micro LED array according to clause 11, wherein the reflective layer is further provided between the first thermal conductive layer and the second thermal conductive layer.
13. The micro LED array according to clause 10, wherein the first thermal conductive layer is further provided between the bottom surface of the mesa structure and the reflective layer, the bottom connect structure passing through the first thermal conductive layer and the reflective layer to connect the bottom of the mesa structure, wherein the micro LED structure further comprises an isolation ring provided between the bottom connect structure and the reflective layer to isolate the bottom connect structure from the reflective layer.
14. The micro LED array according to clause 13, wherein a material of the isolation ring is a dielectric material.
15. The micro LED array according to any one of clauses 4 to 9, wherein the mesa structure comprises:
   a P-type semiconductor layer;
   a light emitting layer formed on the P-type semiconductor layer; and
   an N-type semiconductor layer formed on the light emitting layer; and
   the micro LED array further comprises a second N-type semiconductor layer formed on a top the micro LED array.
16. The micro LED array according to clause 15, further comprising a top conductive layer provided on the second N-type semiconductor layer.
17. The micro LED array according to clause 15, further comprising a top connecting structure provided passing through the second thermal conductive layer to connect the second N-type semiconductor layer with a top pad on the IC backplane.
18. The micro LED array according to any one of clauses 1 to 9, further comprising a top conductive layer provided on a top the micro LED array.
19. The micro LED array according to any one of clauses 1 to 9, further comprising a bottom conductive layer provided at the bottom of the mesa structure.
20. A micro LED display panel, comprising:
   an integrated circuit (IC) backplane comprising a bottom pad array, the bottom pad array comprising a plurality of bottom pads; and
   a micro LED array, comprising a plurality of micro LED structure, according to any one of clauses 1 to 19 provided on the IC backplane;
   wherein one micro LED structure of the plurality of micro LED structures is electrically connected with one bottom pad of the plurality of bottom pads.
21. The micro LED display panel according to clause 20, wherein the micro LED array further comprises a first bonding layer provided at a bottom of the micro LED array; and
the IC backplane comprises a second bonding layer and a substrate layer, the second bonding layer provided at a top of the substrate layer; wherein the first bonding layer and the second bonding layer are bonded.
22. The micro LED display panel according to clause 21, wherein a material of the first bonding layer and the second bonding layer is an electrically insulative material with high thermal conductivity.
23. The micro LED display panel according to clause 22, wherein a thermal conductivity of the electrically insulative material of the first bonding layer and the second bonding layer is greater than 300 W/mK.
24. The micro LED display panel according to clause 23, wherein the electrically insulative material of the first bonding layer and the second bonding layer is AlN, SiC, Boron, Nitride, diamond, or diamond-like carbon.
25. The micro LED display panel according to clause 21, wherein a material of the first bonding layer and the second bonding layer is a dielectric layer.
26. The micro LED display panel according to clause 25, wherein the material of the first bonding layer and the second bonding layer is SiO₂, SiN, or SiCN.
27. The micro LED display panel according to clause 21, wherein a material of the first bonding layer and a material of the second bonding layer are the same.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED array comprising a plurality of micro LED structures, each of the micro LED structures comprising:
a mesa structure;
a first thermal conductive layer formed surrounding a sidewall of the mesa structure, wherein a material of the first thermal conductive layer is an electrically insulative material with high thermal conductivity; and
a bottom connect structure provided at a bottom of the mesa structure to electrically connect the mesa structure to a bottom pad of an integrated circuit (IC) backplane.

2. The micro LED array according to claim 1, wherein a thermal conductivity of the electrically insulative material of the first thermal conductive layer is greater than 300 W/mK.

3. The micro LED array according to claim 2, wherein the material of the first thermal conductive layer is AlN, SiC, Boron, Nitride, diamond, or diamond-like carbon.

4. The micro LED array according to claim 1, further comprising a second thermal conductive layer filled between adjacent ones of micro LED structures, wherein a material of the second thermal conductive layer is a material with high thermal conductivity.

5. The micro LED array according to claim 4, wherein a thermal conductivity of the material of the second thermal conductive layer is greater than 300 W/mK.

6. The micro LED array according to claim 5, wherein the material of the second thermal conductive layer is electrically insulative.

7. The micro LED array according to claim 6, wherein the material of the second thermal conductive layer is AlN, SiC, Boron, Nitride, diamond, or diamond-like carbon.

8. The micro LED array according to claim 5, wherein the material of the second thermal conductive layer is electrically conductive.

9. The micro LED array according to claim 8, wherein the material of the second thermal conductive layer is Ag, Cu, Al, Graphite, or Graphene.

10. The micro LED array according to claim 4, further comprising a reflective layer provided on the sidewall of the mesa structure and a bottom surface of the mesa structure, wherein the first thermal conductive layer is provided between the sidewall of the mesa structure and the reflective layer.

11. The micro LED array according to claim 10, wherein the first thermal conductive layer is further formed on a top surface of the second thermal conductive layer.

12. The micro LED array according to claim 11, wherein the reflective layer is further provided between the first thermal conductive layer and the second thermal conductive layer.

13. The micro LED array according to claim 10, wherein the first thermal conductive layer is further provided between the bottom surface of the mesa structure and the reflective layer, the bottom connect structure passing through the first thermal conductive layer and the reflective layer to connect the bottom of the mesa structure, wherein the micro LED structure further comprises an isolation ring provided between the bottom connect structure and the reflective layer to isolate the bottom connect structure from the reflective layer.

14. The micro LED array according to claim 13, wherein a material of the isolation ring is a dielectric material.

15. The micro LED array according to claim 4, wherein the mesa structure comprises:
a P-type semiconductor layer;
a light emitting layer formed on the P-type semiconductor layer; and
an N-type semiconductor layer formed on the light emitting layer; and
the micro LED array further comprises a second N-type semiconductor layer formed on a top the micro LED array.

16. The micro LED array according to claim 15, further comprising a top conductive layer provided on the second N-type semiconductor layer.

17. The micro LED array according to claim 15, further comprising a top connecting structure provided passing through the second thermal conductive layer to connect the second N-type semiconductor layer with a top pad on the IC backplane.

18. The micro LED array according to claim 1, further comprising a top conductive layer provided on a top the micro LED array.

19. The micro LED array according to claim 1, further comprising a bottom conductive layer provided at the bottom of the mesa structure.

20. A micro LED display panel, comprising:
an integrated circuit (IC) backplane comprising a bottom pad array, the bottom pad array comprising a plurality of bottom pads; and
a micro LED array, comprising a plurality of micro LED structure, provided on the IC backplane, wherein each of the micro LED structures comprises:
a mesa structure;
a first thermal conductive layer formed surrounding a sidewall of the mesa structure, wherein a material of the first thermal conductive layer is an electrically insulative material with high thermal conductivity; and
a bottom connect structure provided at a bottom of the mesa structure to electrically connect the mesa structure to a bottom pad of an integrated circuit (IC) backplane; and
wherein one micro LED structure of the plurality of micro LED structures is electrically connected with one bottom pad of the plurality of bottom pads.

21. The micro LED display panel according to claim 20, wherein the micro LED array further comprises a first bonding layer provided at a bottom of the micro LED array; and
the IC backplane comprises a second bonding layer and a substrate layer, the second bonding layer provided at a top of the substrate layer; wherein the first bonding layer and the second bonding layer are bonded.

22. The micro LED display panel according to claim 21, wherein a material of the first bonding layer and the second bonding layer is an electrically insulative material with high thermal conductivity.

23. The micro LED display panel according to claim 22, wherein a thermal conductivity of the electrically insulative material of the first bonding layer and the second bonding layer is greater than 300 W/mK.

24. The micro LED display panel according to claim 23, wherein the electrically insulative material of the first bonding layer and the second bonding layer is AlN, SiC, Boron, Nitride, diamond, or diamond-like carbon.

25. The micro LED display panel according to claim 21, wherein a material of the first bonding layer and the second bonding layer is a dielectric layer.

26. The micro LED display panel according to claim 25, wherein the material of the first bonding layer and the second bonding layer is SiO₂, SiN, or SiCN.

27. The micro LED display panel according to claim 21, wherein a material of the first bonding layer and a material of the second bonding layer are the same.
